(19) United States
(12) Patent Application Publication
(10) Pub. No.: US 2025/0022897 A1
(43) Pub. Date: Jan. 16, 2025

(54) LIGHT DETECTION DEVICE AND OPTICAL FILTER

(71) Applicant: SONY SEMICONDUCTOR SOLUTIONS CORPORATION, KANAGAWA (JP)

(72) Inventors: HIROSHI ISOBE, KANAGAWA (JP); ATSUSHI TODA, KANAGAWA (JP); MASANAGA FUKASAWA, KANAGAWA (JP)

(21) Appl. No.: 18/715,239

(22) PCT Filed: Dec. 8, 2021
(86) PCT No.: PCT/JP2021/045114

§ 371 Date: May 31, 2024

(51) Int. Cl. H01L 27/146

(52) U.S. Cl. CPC H01L 27/14621

(57) ABSTRACT

A light detection device of an embodiment of the present disclosure includes: a filter including a metal film provided with a plurality of openings each having a size equal to or less than a wavelength of incident light; a barrier metal provided on a corner of the filter, and a photoelectric converter that converts light entering through the filter into an electric charge.

### TECHNICAL FIELD

The present disclosure relates to a light detection device and an optical filter.

### BACKGROUND ART

There has been proposed an imaging device that includes a metallic thin-film filter and detects light of four or more wavelength bands (four or more bands) (multiple spectra) by means of surface plasmons (PTL 1).

### CITATION LIST

### Patent Literature

PTL 1: Japanese Unexamined Patent Application Publication No. 2018-98342

### SUMMARY OF INVENTION

It is desirable to improve the reliability of a device that detects light.

It is desired to provide a light detection device that makes it possible to improve the reliability.

A light detection device of an embodiment of the present disclosure includes: a filter including a metal film provided with a plurality of openings each having a size equal to or less than a wavelength of incident light; a barrier metal provided on a corner of the filter; and a photoelectric converter that converts light entering through the filter into an electric charge.

An optical filter of an embodiment of the present disclosure includes: a metal film provided with a plurality of openings each having a size equal to or less than a wavelength of incident light; and a barrier metal provided on a corner of the metal film.

### BRIEF DESCRIPTION OF DRAWINGS

FIG. 1 is a block diagram illustrating an example of an entire configuration of an imaging device according to an embodiment of the present disclosure.

FIG. 2 is a diagram illustrating an example of a planar configuration of the imaging device according to the embodiment of the present disclosure.

FIG. 3 is a diagram illustrating an example of a cross-sectional configuration of the imaging device according to the embodiment of the present disclosure.

FIG. 4 is a diagram illustrating an example of a planar configuration of a filter of the imaging device according to the embodiment of the present disclosure.

FIG. 5 is a diagram illustrating an example of a cross-sectional configuration of the filter of the imaging device according to the embodiment of the present disclosure.

FIG. 6A is a diagram illustrating an example of a method of producing the filter of the imaging device according to the embodiment of the present disclosure.

FIG. 6B is a diagram illustrating the example of the method of producing the filter of the imaging device according to the embodiment of the present disclosure.

FIG. 6C is a diagram illustrating the example of the method of producing the filter of the imaging device according to the embodiment of the present disclosure.

FIG. 6D is a diagram illustrating the example of the method of producing the filter of the imaging device according to the embodiment of the present disclosure.

FIG. 6E is a diagram illustrating the example of the method of producing the filter of the imaging device according to the embodiment of the present disclosure.

FIG. 6F is a diagram illustrating the example of the method of producing the filter of the imaging device according to the embodiment of the present disclosure.

FIG. 6G is a diagram illustrating the example of the method of producing the filter of the imaging device according to the embodiment of the present disclosure.

FIG. 6H is a diagram illustrating the example of the method of producing the filter of the imaging device according to the embodiment of the present disclosure.

FIG. 7 is a diagram illustrating an example of a cross-sectional configuration of a filter of the imaging device according to a modification example.

FIG. 8 is a block diagram illustrating a configuration example of an electronic apparatus including the imaging device.

FIG. 9 is a block diagram depicting an example of schematic configuration of a vehicle control system.

FIG. 10 is a diagram of assistance in explaining an example of installation positions of an outside-vehicle information detecting section and an imaging section.

FIG. 11 is a view depicting an example of a schematic configuration of an endoscopic surgery system.

FIG. 12 is a block diagram depicting an example of a functional configuration of a camera head and a camera control unit (CCU).

### MODES FOR CARRYING OUT THE INVENTION

With reference to the drawings, an embodiment of the present disclosure will be described in detail below. It is to be noted that the description will be given in the following order.
1. Embodiment
2. Modification Example
3. Application Example
4. Practical Application Examples

### 1. Embodiment

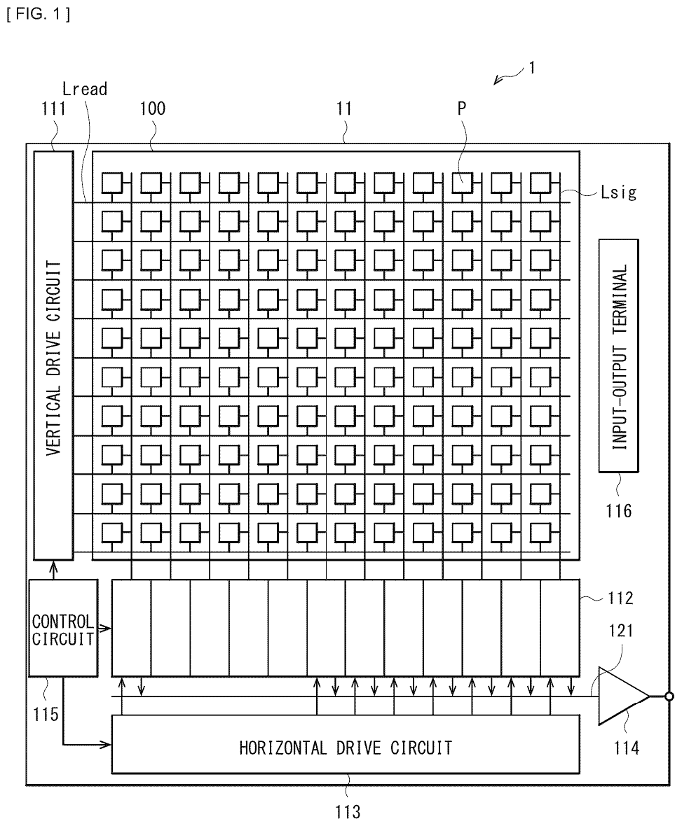

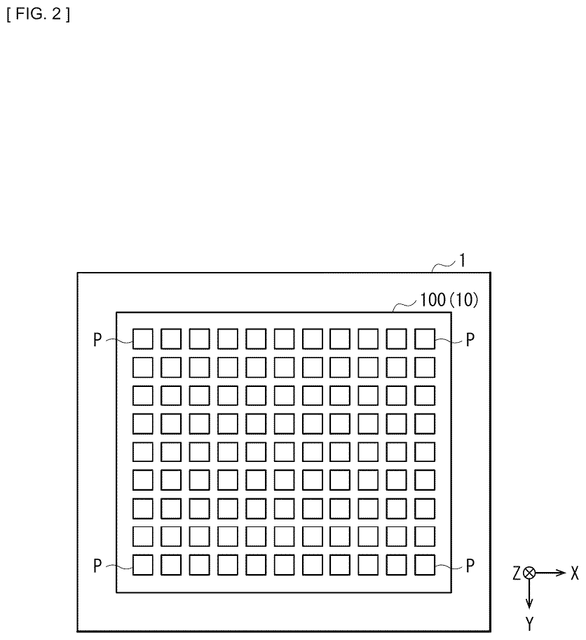

FIG. 1 is a block diagram illustrating an example of an entire configuration of an imaging device that is an example of a light detection device according to an embodiment of the present disclosure. FIG. 2 is a diagram illustrating an example of a planar configuration of the imaging device. An imaging device 1 that is a light detection device is a device that detects incoming light. The imaging device (the light detection device) 1 may be applied to a multispectral camera that is able to detect light of four or more wavelength regions. The imaging device 1 is, for example, a complementary metal-oxide semiconductor (CMOS) image sensor.

In the imaging device 1, pixels Peach including a photoelectric converter are arranged in a matrix. As illustrated in FIG. 2, the imaging device 1 includes, as an imaging area, a region (a pixel section 100) of a plurality of pixels P arranged two-dimensionally in a matrix. The imaging device 1 is usable in an electronic apparatus such as a digital still camera or a video camera. It is to be noted that, as illustrated in FIG. 2, an incident direction of light from a subject is referred to as a Z-axis direction, a right-and-left direction on the plane of paper perpendicular to the Z-axis direction is referred to as an X-axis direction, and an up-and-down direction on the plane of paper perpendicular to the Z-axis and the X-axis is referred to as a Y-axis direction. In the subsequent drawings, the direction may sometimes be represented with reference to a direction of an arrow in FIG. 2.

### [Schematic Configuration of Imaging Device]

The imaging device 1 takes in incident light (image light) from a subject through an optical lens system (not illustrated). The imaging device 1 captures an image of the subject. The imaging device 1 converts an amount of incident light formed as an image on an imaging plane into an electrical signal on a pixel-by-pixel basis, and outputs the electrical signal as a pixel signal. The imaging device 1 includes, in a region around the pixel section 100, for example, a vertical drive circuit 111, a column signal processing circuit 112, a horizontal drive circuit 113, an output circuit 114, a control circuit 115, an input-output terminal 116, etc.

In the pixel section 100, a plurality of pixels P is two-dimensionally arranged in a matrix. The pixel section 100 is provided with multiple pixel rows including a plurality of pixels P arranged in a horizontal direction (a lateral direction on the plane of paper) and multiple pixel columns including a plurality of pixels P arranged in a vertical direction (a longitudinal direction on the plane of paper).

In the pixel section 100, for example, a pixel drive line Lread (a row selection line and a reset control line) is provided for each pixel row, and a vertical signal line Lsig is provided for each pixel column. The pixel drive line Lread is for transmitting a drive signal for readout of a signal from a pixel. One end of the pixel drive line Lread is coupled to an output terminal of the vertical drive circuit 111 corresponding to each pixel row.

The vertical drive circuit 111 includes a shift register, an address decoder, etc. The vertical drive circuit 111 is a pixel drive unit that drives each pixel P in the pixel section 100, for example, on a row-by-row basis. The column signal processing circuit 112 includes an amplifier, a horizontal selection switch, etc. provided for each vertical signal line Lsig. A signal output from each of pixels P of a pixel row selected and scanned by the vertical drive circuit 111 is supplied to the column signal processing circuit 112 through a vertical signal line Lsig.

The horizontal drive circuit 113 includes a shift register, an address decoder, etc., and drives each horizontal selection switch of the column signal processing circuit 112 in turn while scanning. By this selective scanning by the horizontal drive circuit 113, a signal of each pixel transmitted through each respective vertical signal line Lsig is output to a horizontal signal line 121 in turn, and is transmitted to the outside of a semiconductor substrate 11 through the horizontal signal line 121.

The output circuit 114 performs signal processing on signals sequentially supplied from each of the column signal processing circuits 112 through the horizontal signal line 121 and outputs the processed signals. For example, the output circuit 114 performs only buffering in some cases, and performs black level adjustment, column variation correction, a variety of digital signal processing, etc. in other cases.

A circuit part including the vertical drive circuit 111, the column signal processing circuit 112, the horizontal drive circuit 113, the horizontal signal line 121, and the output circuit 114 may be formed on the semiconductor substrate 11, or may be provided in an external control IC. Furthermore, the circuit part may be formed on another substrate coupled by cable or something.

The control circuit 115 receives a clock given from the outside of the semiconductor substrate 11, data that orders an operation mode, etc., and outputs data such as internal information of the imaging device 1. Furthermore, the control circuit 115 includes a timing generator that generates various timing signals, and performs control of driving the peripheral circuits such as the vertical drive circuit 111, the column signal processing circuit 112, and the horizontal drive circuit 113 on the basis of various timing signals generated by the timing generator. The input-output terminal 116 exchanges a signal with the outside.

### [Configuration of Pixel]

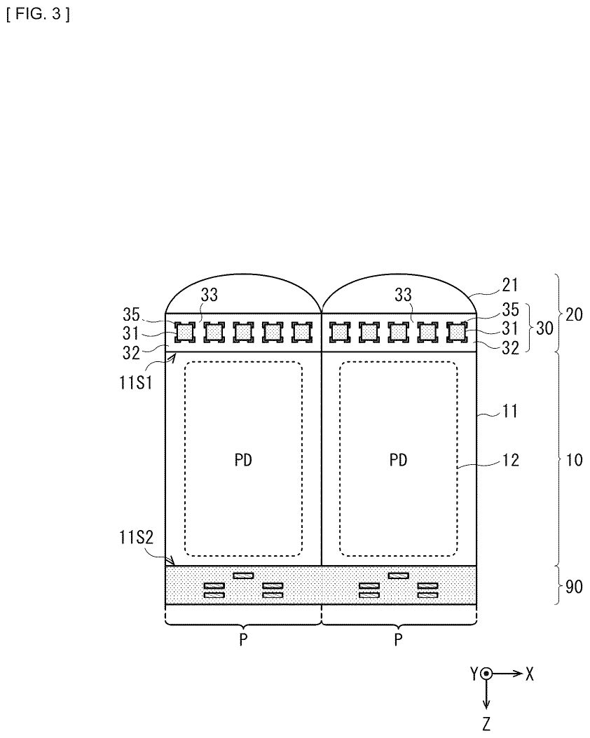

FIG. 3 is a diagram illustrating an example of a cross-sectional configuration of the imaging device according to the embodiment. For example, the imaging device 1 has a configuration in which a light receiving unit 10, a light guiding unit 20, and a multi-layer wiring layer 90 are stacked in the Z-axis direction. The light receiving unit 10 includes the semiconductor substrate 11 having first and second surfaces 11S1 and 11S2 opposed to each other. The light guiding unit 20 is provided on the first surface 11S1 side of the semiconductor substrate 11, and the multi-layer wiring layer 90 is provided on the second surface 11S2 side of the semiconductor substrate 11. It may be said that the light guiding unit 20 is provided on the side from which light from the optical lens system enters, and the multi-layer wiring layer 90 is provided on the side opposite to the side from which light enters. The imaging device 1 is a so-called back-illuminated imaging device.

The semiconductor substrate 11 includes, for example, a silicon substrate. A photoelectric converter 12 is, for example, a photodiode (PD), and has a p-n junction in a predetermined region of the semiconductor substrate 11. The semiconductor substrate 11 is embedded with a plurality of the photoelectric converters 12. The photoelectric converter 12 may photoelectrically convert incoming light and generate an electric charge. In the light receiving unit 10, the plurality of photoelectric converters 12 is provided along the first and second surfaces 11S1 and 11S2 of the semiconductor substrate 11. It is to be noted that the semiconductor substrate 11 may include another semiconductor material.

For example, the multi-layer wiring layer 90 has a configuration in which multiple wiring layers are stacked with an interlayer insulating layer inserted between them. The multiple wiring layers of the multi-layer wiring layer 90 are formed, for example, using a material such as aluminum (Al), copper (Cu), or tungsten (W). The wiring layers may be formed using polysilicon (poly-Si). The interlayer insulating layer is formed of, for example, a single-layer film including, of materials such as silicon oxide (SiOₓ), silicon nitride (SiNₓ), and silicon oxynitride (SiOₓN_{y}), one, or a multi-layered film including two or more of these materials.

In the semiconductor substrate 11 and the multi-layer wiring layer 90, there is formed a circuit (for example, a transfer transistor, a reset transistor, an amplification transistor, etc.) for reading a pixel signal based on an electric charge generated by the photoelectric converter 12. Furthermore, for example, the vertical drive circuit 111, the column signal processing circuit 112, the horizontal drive circuit 113, the output circuit 114, the control circuit 115, the input-output terminal 116, etc. described above are formed in the semiconductor substrate 11 and the multi-layer wiring layer 90.

A pixel P includes, for example, the photoelectric converter 12, a transfer transistor, a floating diffusion (FD), a reset transistor, an amplification transistor, etc. The photoelectric converter 12 converts incoming light into an electric charge, and accumulates the photoelectrically-converted electric charge. The transfer transistor transfers the electric charge that has been photoelectrically-converted and accumulated by the photoelectric converter 12 to the FD. The FD is an electric charge accumulator, and accumulates the transferred electric charge. The amplification transistor outputs a pixel signal based on the electric charge accumulated in the FD. The reset transistor resets the electric charge accumulated in the FD, and may reset the voltage of the FD.

The light guiding unit 20 includes a lens unit 21 that concentrates light and a filter 30. The light guiding unit 20 is stacked on the light receiving unit 10 in a thickness direction perpendicular to the first surface11S1 of the semiconductor substrate 11. The light guiding unit 20 is stacked on the light receiving unit 10, and guides light entering from above in FIG. 3 to the side of the light receiving unit 10.

The lens unit 21 is an optical member called an on-chip lens, and is provided on top of the filter 30. Light from a subject enters the lens unit 21, for example, through the optical lens system such as an imaging lens. The lens unit 21 includes a material that allows light to transmit therethrough, and guides incoming light toward the filter 30 and the photoelectric converter 12.

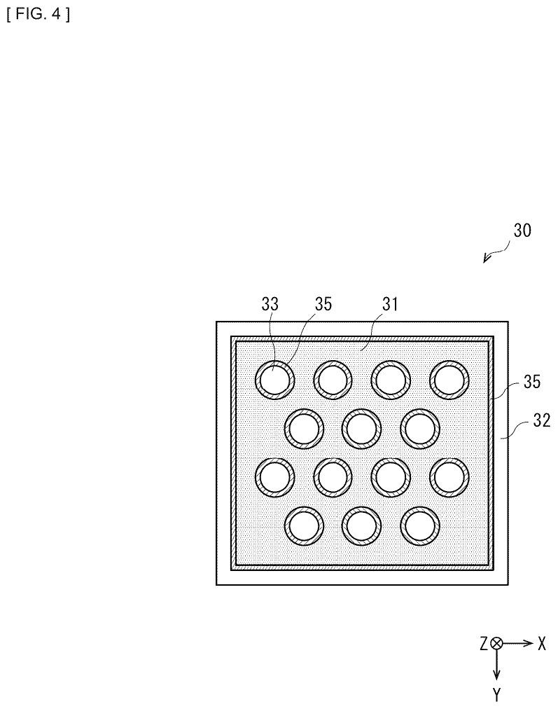

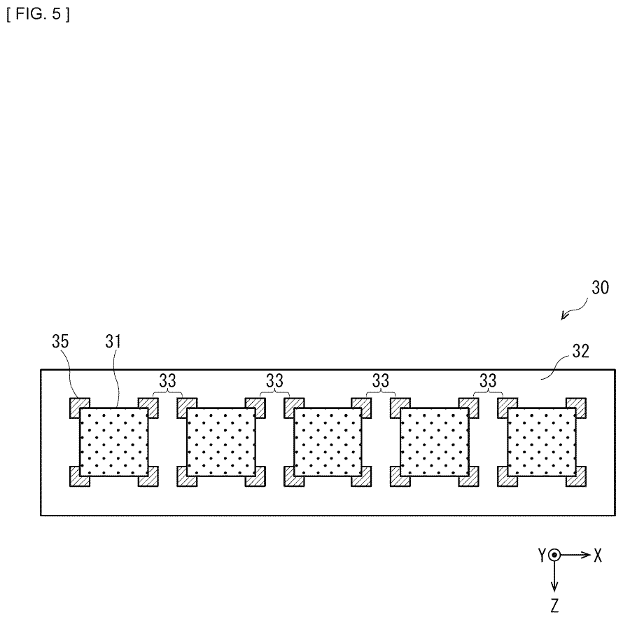

FIG. 4 is a diagram illustrating an example of a planar configuration of a filter of the imaging device according to the embodiment. FIG. 5 is a diagram illustrating an example of a cross-sectional configuration of the filter of the imaging device according to the embodiment. The filter 30 is an optical filter, and includes a metal film 31 provided with a plurality of openings 33 as illustrated in FIGS. 3 to 5. The filter 30 is the filter 30 including the metal film 31, and may be said to be a metal thin-film filter. By means of surface plasmons, the filter 30 selectively allows light of a specific wavelength region to propagate. As illustrated in FIG. 3, the filter 30 is located above the photoelectric converter 12 in a direction in which light enters. The filter 30 is provided one for each pixel Por one for several pixels P.

The metal film 31 is a metal thin film that allows plasmon resonance to occur, and includes, for example, aluminum (Al). It is to be noted that the metal film 31 may include another material that may allow plasmon resonance to occur. For example, the metal film 31 may include a metal material such as silver (Ag), gold (Au), copper (Cu), titanium (Ti), or tungsten (W). The metal film 31 has a thickness that allows the plasmon resonance to occur. The thickness (the length) of the metal film 31 in the Z-axis direction is, for example, equal to or less than several hundred nm or equal to or less than several tens of nm. As an example, the metal film 31 has a film thickness of 180 nm.

The openings 33 are each an opening of a size equal to or less than a predetermined wavelength of incoming light. For example, the openings 33 each have a size equal to or less than a wavelength of visible light. In the example illustrated in FIGS. 3 to 5, the openings 33 are holes that go through the metal film 31, and are periodically provided. For example, the openings 33 are two-dimensionally provided in the metal film 31. The multiple openings 33 are formed at regular intervals, and are each a cylindrical hole. For example, as illustrated in FIG. 4, the multiple openings 33 are arranged in a honeycomb pattern at equal intervals. It may be said that the filter 30 has a periodic hole array. It is to be noted that the metal film 31 may include openings 33 that are through holes and openings 33 that are non-through holes.

In the example illustrated in FIGS. 3 to 5, the filter (the optical filter) 30 includes a dielectric 32 around the metal film 31. The dielectric 32 includes, for example, a silicon oxide film (SiO). The dielectric 32 is provided to cover a surface of the metal film 31, and is provided on the inside of the openings 33 as well. The dielectric 32 also serves as a protective film (a protective layer).

It is to be noted that the dielectric 32 may include another insulating material such as silicon nitride (SiN) or silicon oxynitride (SiON). The dielectric 32 may include a material such as hafnium oxide (HfO), aluminum oxide (AlO), titanium oxide (TiO), zirconium oxide (ZrO), tantalum oxide (TaO), or magnesium fluoride (MgF).

If light enters the filter 30, surface plasmons may be excited on the surface of the metal film 31. It may be said that exposure of the filter 30 to light induces surface plasmons at the interface between the metal film 31 and the dielectric 32. If surface plasmon resonance occurs by light entering the filter 30, surface plasmons propagate through the surface of the metal film 31 and the openings 33, and light of a specific wavelength (frequency) is guided to the side of the photoelectric converter 12. In a case where light has entered the filter 30, due to extraordinary transmission caused by the surface plasmon resonance, only light of a specific wavelength is allowed to be transmitted.

The wavelength of this transmitted light varies depending on the size and shape of the openings 33, the interval between the openings 33, etc. Thus, by adjusting the size of the openings 33, the interval between the openings 33, etc., it becomes possible to allow light of a specific wavelength to propagate, and it becomes possible to guide light of a wavelength of any color to the side of the photoelectric converter 12. As an example, the openings 33 of the filter 30 of each pixel P are set to have a size equal to or less than a wavelength region of light to be detected to allow light of a wavelength to be detected to travel to the photoelectric converter 12.

The light transmitted through the lens unit 21 and the filter 30 enters the photoelectric converter 12 of a pixel P. The photoelectric converter 12 receives the light entering through the filter 30, and generates an electric charge in accordance with an amount of the received light. Each pixel P generates and outputs a pixel signal based on the electric charge converted by the photoelectric converter 12. The imaging device 1 is able to obtain pixel signals of multiple color components (for example, four or more color components). The imaging device 1 according to the present embodiment is able to detect multiple spectra, thus it is possible to acquire image data including four or more color components.

In the imaging device 1 according to the present embodiment, barrier metals 35 are provided as illustrated in FIGS. 3 to 5. The barrier metals 35 are provided on the corners of the metal film 31 of the filter 30. Thus, it is possible to suppress migration of the metal film 31.

If the imaging device 1 does not include the barrier metals 35, migration is likely to occur at the corners of the metal film 31. By checking out a hydrostatic stress gradient that is strongly correlated with migration, for example, through a stress simulation, an experiment, etc., it becomes possible to confirm that migration is likely to occur at the corners of the metal film 31.

As compared with a case where the imaging device 1 does not include the barrier metals 35, the imaging device 1 provided with the barrier metals 35 is able to suppress the occurrence of migration caused by ingress of moisture, etc. For example, in a case where the metal film 31 includes aluminum, it is possible to prevent the occurrence of migration of aluminum resulting in the frequent occurrence of defects.

Furthermore, in the present embodiment, the barrier metals 35 are provided on the corners of the metal film 31 to allow a large portion of the metal film 31 to be exposed. It may be said that the barrier metals 35 are provided on corners of the openings 33 on the incident side of light and the corners of the openings 33 on the side of the photoelectric converter 12. It is to be noted that the corners are each a portion connecting adjacent surfaces (sides). The corners are portions connecting multiple surfaces included in the metal film 31 (or the openings 33), and may be said to be portions where the multiple surfaces are in contact with one another. It is to be noted that the corners may include a rounded portion. The corners may be chamfered, or may include, for example, an arc-shaped portion.

In the example illustrated in FIGS. 3 to 5, the barrier metals 35 each have an L-shape, and are formed on the four corners of the metal film 31. A portion of the metal film 31 other than the corners is exposed to the outside. Thus, in the imaging device 1 according to the present embodiment, it is possible to effectively prevent migration while avoiding hindering the occurrence of plasmon resonance in the metal film 31. Therefore, in the present embodiment, it is possible to improve the reliability of the imaging device 1.

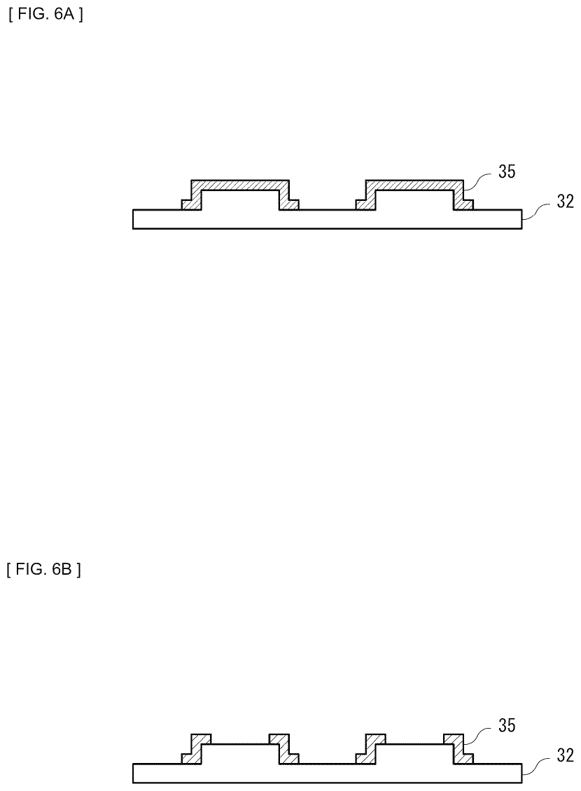

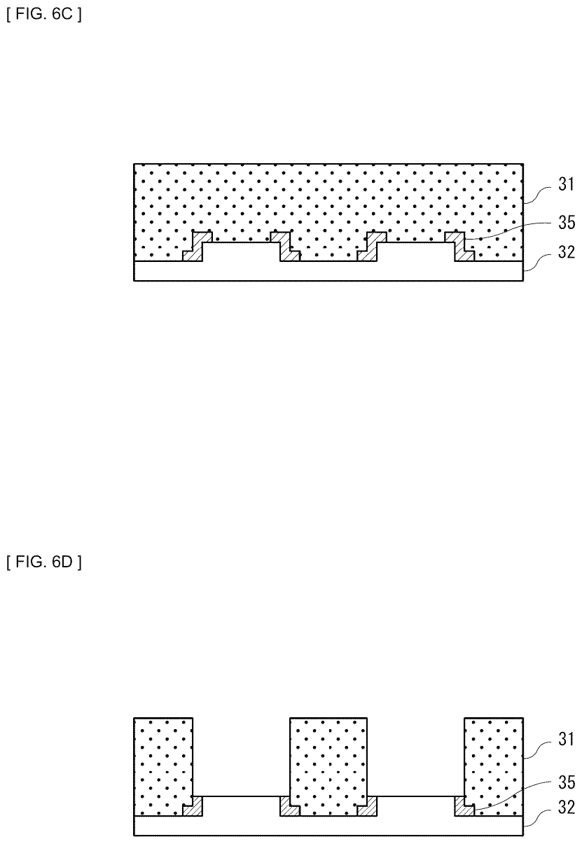

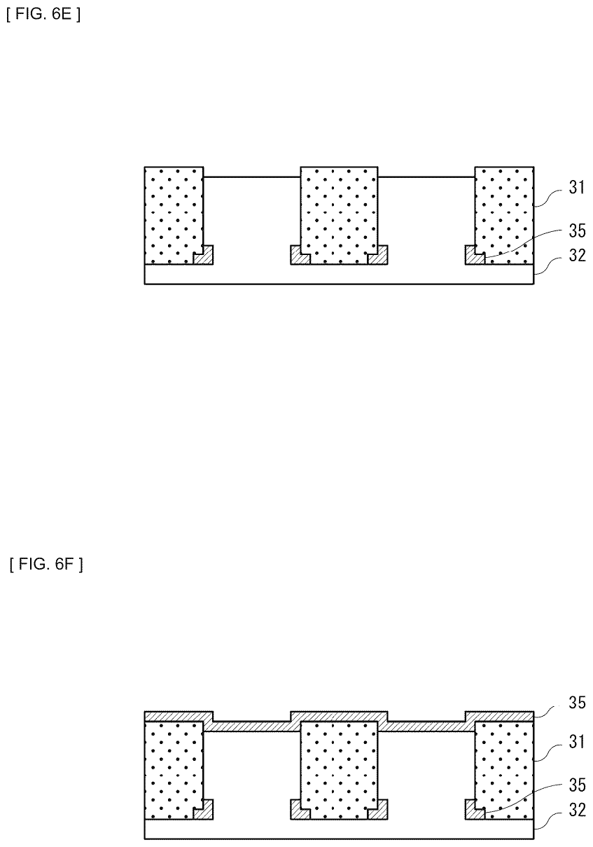

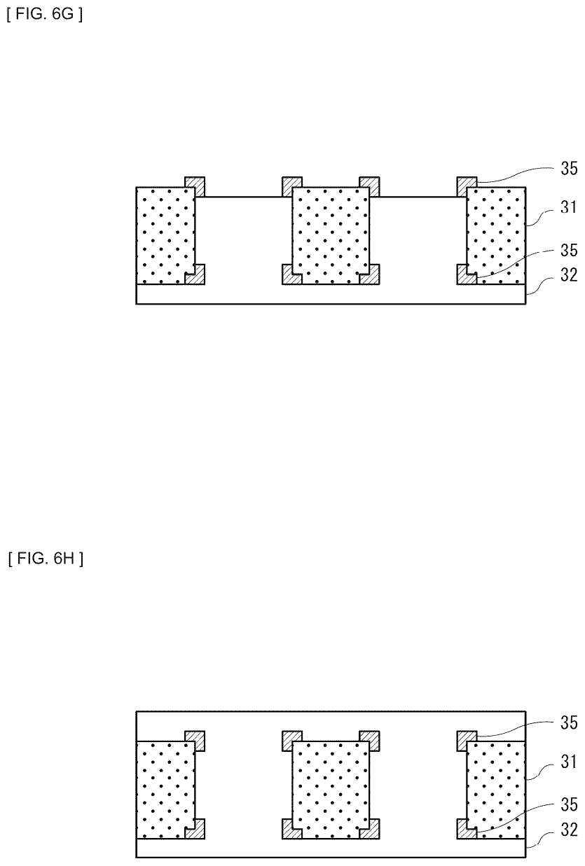

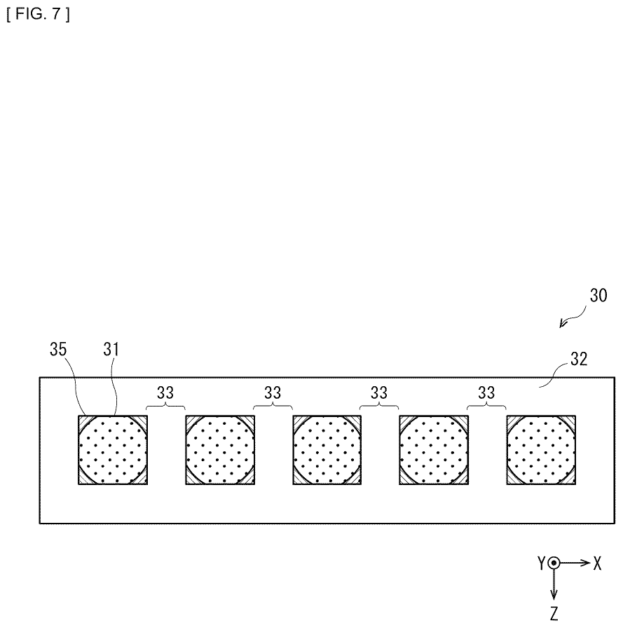

FIGS. 6A to 6H are diagrams illustrating an example of a method of producing the filter 30 of the imaging device according to the embodiment. First, as illustrated in FIG. 6A, a silicone oxide film that is the dielectric 32 and aluminum films that are the barrier metals 35 are formed on the semiconductor substrate 11. Then, as illustrated in FIG. 6B, unwanted portions of the barrier metals 35 are selectively removed by lithography and etching.

Next, as illustrated in FIG. 6C, the metal film 31 is formed on top of the dielectric 32 and the barrier metals 35. Then, as illustrated in FIG. 6D, unwanted portions of the metal film 31 are removed by lithography and etching. Furthermore, as illustrated in FIG. 6E, as the dielectric 32, a silicone oxide film is formed between the metal films 31. After that, as illustrated in FIG. 6F, as the barrier metal 35, an aluminum film is formed on top of the metal films 31 and the dielectric 32.

Next, as illustrated in FIG. 6G, unwanted portions of the metal film 31 are removed by lithography and etching. Then, as illustrated in FIG. 6H, a silicone oxide film that is the dielectric 32 is formed on top of the metal films 31 and the barrier metals 35.

The filter 30 is able to be produced by the production method described above. It is to be noted that the imaging device 1 illustrated in FIG. 3 is able to be manufactured by sequentially forming the multi-layer wiring layer 90, the lens unit 21, etc. Furthermore, the above-described production method is merely an example, and another production method may be adopted.

### [Action and Effect]

The light detection device (the imaging device 1) according to the present embodiment includes: the filter 30 including the metal film 31 provided with the plurality of openings 33 each having a size equal to or less than a wavelength of incident light; the barrier metals 35 provided on the corners of the filter 30; and the photoelectric converter 12 that converts light entering through the filter 30 into an electric charge.

The imaging device 1 according to the present embodiment includes the barrier metals 35 provided on the corners of the filter 30, which makes it possible to suppress the occurrence of migration of the metal film 31. The barrier metals 35 are provided only on the corners of the filter 30, thus it is possible to avoid hindering the occurrence of plasmon resonance in the metal film 31, and is possible to effectively prevent migration. Therefore, it is possible to improve the reliability.

Subsequently, a modification example of the present disclosure is described. In the following, a similar component to the above-described embodiment is assigned the same reference numeral, and its description is omitted accordingly.

### 2. Modification Example

In the above-described embodiment, a configuration example of the barrier metals 35 has been described; however, the configuration of the barrier metals 35 is not limited to this. FIG. 7 is a diagram illustrating an example of a cross-sectional configuration of a filter of the imaging device 1 according to the modification example.

For example, the barrier metals 35 may be provided in the corners of the metal film 31 as in the example illustrated in FIG. 7. It may be said that the barrier metals 35 are disposed to substitute for the corners (the four corners) of the metal film 31. A surface of the barrier metal 35 in contact with the metal film 31 may be a curved surface as in the example illustrated in FIG. 7. In a case of FIG. 7, the barrier metals 35 each have an R-shape. Furthermore, it may be said that the metal film 31 has the R-shaped corners.

Also in the case of the present modification example, by providing the barrier metals 35 in the corners of the metal film 31, it becomes possible to avoid hindering the occurrence of plasmon resonance in the metal film 31 and to effectively prevent migration. As with the case of the above-described embodiment, it is possible to improve the reliability.

### 3. Application Example

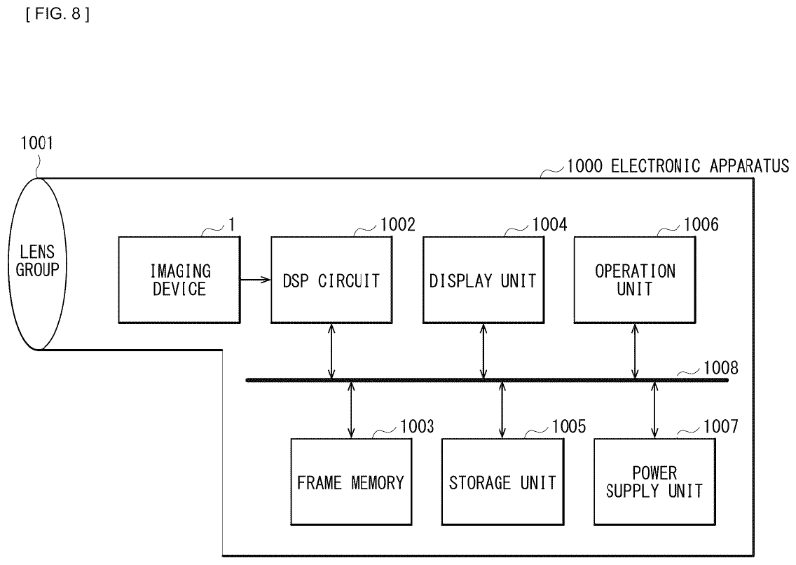

The above-described imaging device 1, etc. are applicable to all types of electronic apparatuses including an imaging function, for example, a camera system such as a digital still camera or a video camera, a cell phone having an imaging function, etc. FIG. 8 illustrates a schematic configuration of an electronic apparatus 1000.

The electronic apparatus 1000 includes, for example, a lens group 1001, the imaging device 1, a digital signal processor (DSP) circuit 1002, a frame memory 1003, a display unit 1004, a recorder 1005, an operation unit 1006, and a power supply unit 1007, and these are coupled to one another through a bus line 1008.

The lens group 1001 takes in incident light (image light) from a subject and forms an image on the imaging plane of the imaging device 1. The imaging device 1 converts an amount of the incident light formed as an image on the imaging plane by the lens group 1001 into an electrical signal on a pixel-by-pixel basis, and supplies the electrical signal as a pixel signal to the DSP circuit 1002.

The DSP circuit 1002 is a signal processing circuit that processes a signal supplied from the imaging device 1. The DSP circuit 1002 outputs image data obtained by processing the signal from the imaging device 1. The frame memory 1003 temporarily holds therein the image data processed by the DSP circuit 1002 on a frame-by-frame basis.

The display unit 1004 includes, for example, a panel-type display device such as a liquid crystal panel or an organic electroluminescence (EL) panel, and records image data of a moving image or a still image captured by the imaging device 1 on a recording medium such as a semiconductor memory or a hard disk.

The operation unit 1006 outputs, in accordance with an operation by a user, an operation signal related to various functions that the electronic apparatus 1000 has. The power supply unit 1007 fittingly supplies various kinds of electric power that is operating power of the DSP circuit 1002, the frame memory 1003, the display unit 1004, the recorder 1005, and the operation unit 1006 to these units to be supplied with.

Furthermore, the technique according to the present disclosure may be applied to, for example, as below, various cases of sensing light such as visible light, infrared light, ultraviolet light, or X-rays. The light detection device and the optical filter according to the present disclosure are applicable to various apparatuses:
devices that take an image for appreciation, for example, a digital camera, a mobile device with a camera function, etc.
devices used for traffic, for example, an in-vehicle sensor that takes images of the front and rear, the surroundings, the inside, etc. of an automobile for the sake of safe driving such as automatic stop, recognition of a driver's condition, etc., a monitoring camera that monitors running vehicles and a road, a ranging sensor that measures a distance between vehicles or somethings, etc.
devices used in home electric appliances, such as a television, a refrigerator, and an air conditioner, and configured to capture a user's gesture to perform operation of an appliance in accordance with that gesture
devices used for medical care and healthcare, for example, an endoscope, a device that performs angiography by means of infrared light reception, etc.
devices used for security, for example, a surveillance camera for crime prevention, a camera for person authentication, etc.
devices used for beauty, for example, a skin measuring instrument that takes an image of the skin, a microscope that takes an image of the scalp, etc.
devices used for sports, for example, an action camera, a wearable camera, etc. for sports use
devices used for agriculture, for example, a camera, etc. for monitoring the condition of a field or crops.

### 4. Practical Application Examples

### (Example of Practical Application to Moving Body)

The technique according to the present disclosure (the present technology) is applicable to various products. For example, the technique according to the present disclosure may be realized as a device mounted on any of kinds of moving bodies such as a motor vehicle, an electric vehicle, a hybrid electric vehicle, a motorcycle, a bicycle, a personal transporter, an airplane, a drone, a vessel, and a robot.

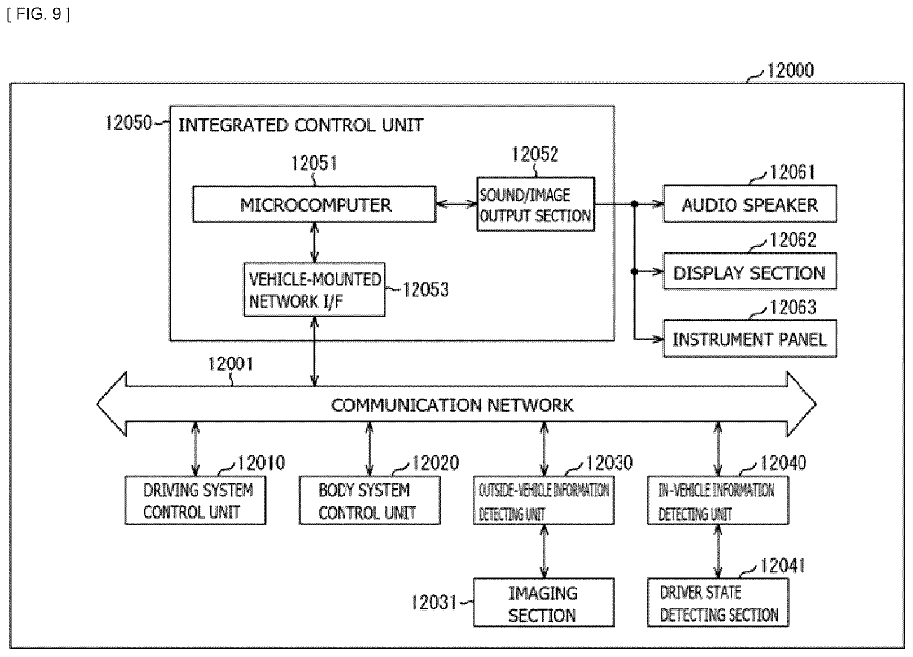

FIG. 9 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 9, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 9, an audio speaker 12061, a display section 12062, and an instrument panel 12063 are illustrated as the output device. The display section 12062 may, for example, include at least one of an on-board display and a head-up display.

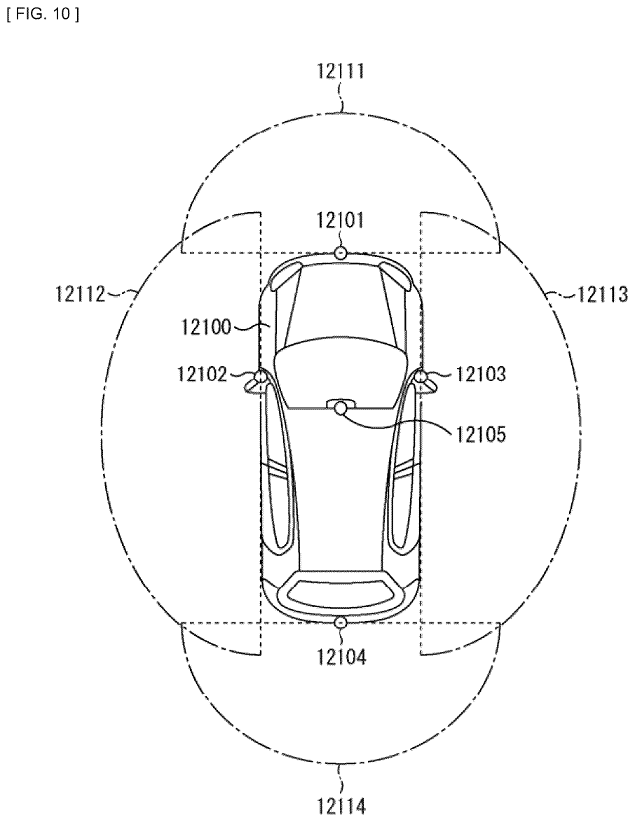

FIG. 10 is a diagram depicting an example of the installation position of the imaging section 12031.

In FIG. 10, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 10 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As above, there has been described an example of the moving body control system to which the technique according to the present disclosure may be applied. The technique according to the present disclosure may be applied to, of the above-described components, for example, the imaging section 12031. Specifically, for example, the imaging device 1 is applicable to the imaging section 12031. By applying the technique according to the present disclosure to the imaging section 12031, it becomes possible to obtain a high-definition taken image with less noise; therefore, it is possible to perform high-precision control using the taken image in the moving body control system.

### (Example of Practical Application to Endoscopic Surgery System)

The technique according to the present disclosure (the present technology) is applicable to various products. For example, the technique according to the present disclosure may be applied to an endoscopic surgery system.

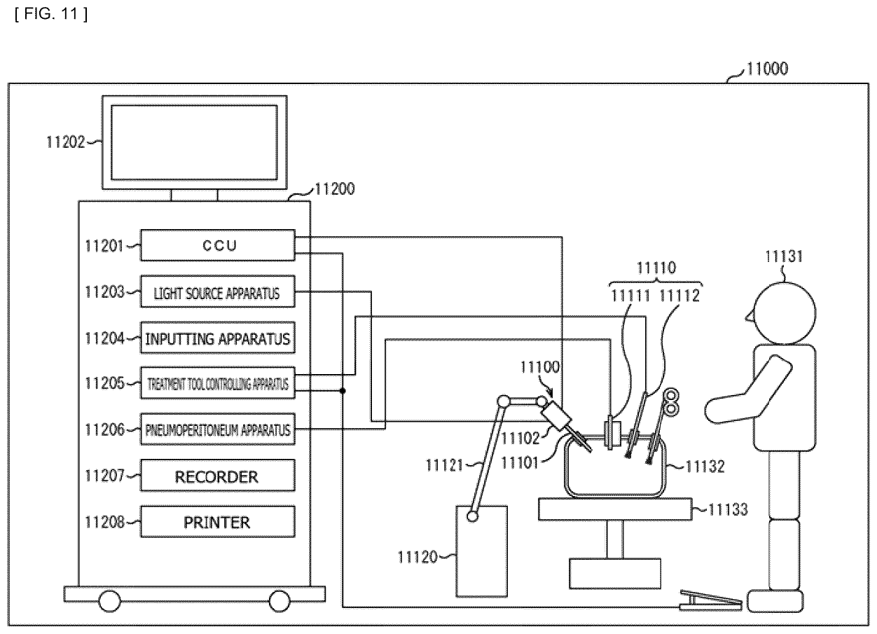

FIG. 11 is a view depicting an example of a schematic configuration of an endoscopic surgery system to which the technology according to an embodiment of the present disclosure (present technology) can be applied.

In FIG. 11, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

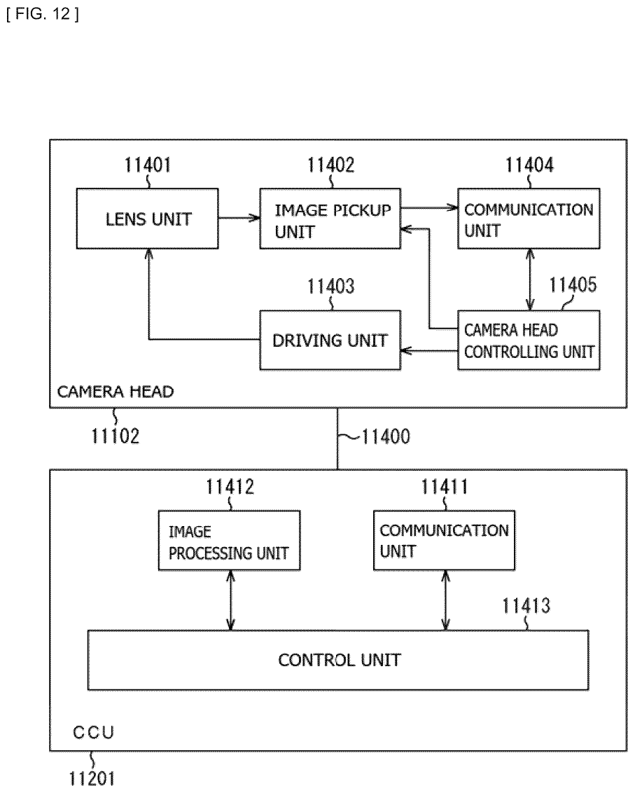

FIG. 12 is a block diagram depicting an example of a functional configuration of the camera head 11102 and the CCU 11201 depicted in FIG. 11.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As above, there has been described an example of the endoscopic surgery system to which the technique according to the present disclosure may be applied. The technique according to the present disclosure may be suitably applied to, of the above-described components, for example, the image pickup unit 11402 provided in the camera head 11102 of the endoscope 11100. By applying the technique according to the present disclosure to the image pickup unit 11402, it becomes possible to make the image pickup unit 11402 highly sensitive; therefore, it is possible to provide the high-definition endoscope 11100.

The present disclosure has been described above with the embodiment, the modification example, the application example, and the practical application examples; however, the present technology is not limited to the above-described embodiment, etc., and it is possible to make various modifications. For example, the above-described modification example has been described as a modification example of the above-described embodiment; furthermore, it is possible to fittingly combine respective configurations of modification examples. For example, the present disclosure is not limited to a back-illuminated image sensor, and is also applicable to a front-illuminated image sensor. The imaging device 1 may be a charge-coupled device (CCD) image sensor.

Furthermore, the light detection device of the present disclosure may take the form of a module into which an imaging unit and a signal processing unit or an optical system are packaged.

Moreover, in the above-described embodiment, etc., there has been described an example of the imaging device that converts an amount of incident light formed as an image on the imaging plane through the optical lens system into an electrical signal on a pixel-by-pixel basis and outputs the electrical signal as a pixel signal; however, the light detection device of the present disclosure is not limited to such an imaging device. For example, it only has to detect and receive light from a subject, generate an electric charge in accordance with an amount of the received light by photoelectric conversion, and accumulate the electric charge. A signal to be output may be a signal of image information, or may be a signal of ranging information.

It is to be noted that the effects described in the present specification are merely an example; the effects of the present disclosure are not limited to those described in the present specification, and the present disclosure may have other effects. Furthermore, the present disclosure may have the following configuration.

(1)

A light detection device including:
a filter including a metal film provided with a plurality of openings each having a size equal to or less than a wavelength of incident light;
a barrier metal provided on a corner of the filter; and
a photoelectric converter that converts light entering through the filter into an electric charge.
   (2)

The light detection device according to (1), in which
the metal film includes a metal thin film that allows plasmon resonance to occur.
   (3)

The light detection device according to (1) or (2), in which
the metal film includes aluminum, silver, or gold.
   (4)

The light detection device according to any one of (1) to (3), in which
the barrier metal includes a material that is less likely to allow migration to occur than the metal film.
   (5)

The light detection device according to any one of (1) to (4), in which
the barrier metal includes titanium, titanium nitride, tantalum, or tantalum nitride.
   (6)

The light detection device according to any one of (1) to (5), in which
the barrier metal is provided on a corner of the opening.
   (7)

The light detection device according to any one of (1) to (6), in which
the barrier metal has an L-shape.
   (8)

The light detection device according to any one of (1) to (7), in which
the opening includes a hole that goes through the metal film, and is periodically provided in the filter, and
the barrier metal is provided on a corner of the hole.
   (9)

The light detection device according to any one of (1) to (8), in which
the barrier metal is provided on a corner of the opening on the incident side of light and a corner of the opening on the side of the photoelectric converter.
   (10)

An optical filter including:
a metal film provided with a plurality of openings each having a size equal to or less than a wavelength of incident light; and
a barrier metal provided on a corner of the metal film.
   (11)

The optical filter according to (10), in which
the metal film includes a metal thin film that allows plasmon resonance to occur.
   (12)

The optical filter according to (10) or (11), in which
the metal film includes aluminum, silver, or gold.
   (13)

The optical filter according to any one of (10) to (12), in which
the barrier metal includes a material that is less likely to allow migration to occur than the metal film.
   (14)

The optical filter according to any one of (10) to (13), in which
the barrier metal includes titanium, titanium nitride, tantalum, or tantalum nitride.
   (15)

The optical filter according to any one of (10) to (14), in which
the barrier metal is provided on a corner of the opening.
   (16)

The optical filter according to any one of (10) to (15), in which
the barrier metal has an L-shape.
   (17)

The optical filter according to any one of (10) to (16), in which
the opening includes a hole that goes through the metal film, and is periodically provided, and
the barrier metal is provided on a corner of the hole.
   (18)

The optical filter according to any one of (10) to (17), in which
the barrier metal is provided on a corner of the opening on the incident side of light and a corner of the opening on the side of the photoelectric converter.

It should be understood by those skilled in the art that various modifications, combinations, sub-combinations, and alterations may occur depending on design requirements and other factors insofar as they are within the scope of the appended claims or the equivalents thereof.

1. A light detection device comprising:
a filter including a metal film provided with a plurality of openings each having a size equal to or less than a wavelength of incident light;
a barrier metal provided on a corner of the filter; and
a photoelectric converter that converts light entering through the filter into an electric charge.

2. The light detection device according to claim 1, wherein
the metal film comprises a metal thin film that allows plasmon resonance to occur.

3. The light detection device according to claim 2, wherein
the metal film includes aluminum, silver, or gold.

4. The light detection device according to claim 1, wherein
the barrier metal includes a material that is less likely to allow migration to occur than the metal film.

5. The light detection device according to claim 1, wherein
the barrier metal includes titanium, titanium nitride, tantalum, or tantalum nitride.

6. The light detection device according to claim 1, wherein
the barrier metal is provided on a corner of the opening.

7. The light detection device according to claim 1, wherein
the barrier metal has an L-shape.

8. The light detection device according to claim 1, wherein
the opening comprises a hole that goes through the metal film, and is periodically provided in the filter, and
the barrier metal is provided on a corner of the hole.

9. The light detection device according to claim 1, wherein
the barrier metal is provided on a corner of the opening on an incident side of light and a corner of the opening on a side of the photoelectric converter.

10. An optical filter comprising:
a metal film provided with a plurality of openings each having a size equal to or less than a wavelength of incident light; and
a barrier metal provided on a corner of the metal film.

11. The optical filter according to claim 10, wherein
the metal film comprises a metal thin film that allows plasmon resonance to occur.

12. The optical filter according to claim 11, wherein
the metal film includes aluminum, silver, or gold.

13. The optical filter according to claim 10, wherein
the barrier metal includes a material that is less likely to allow migration to occur than the metal film.

14. The optical filter according to claim 10, wherein
the barrier metal includes titanium, titanium nitride, tantalum, or tantalum nitride.

15. The optical filter according to claim 10, wherein
the barrier metal is provided on a corner of the opening.

16. The optical filter according to claim 10, wherein
the barrier metal has an L-shape.

17. The optical filter according to claim 10, wherein
the opening comprises a hole that goes through the metal film, and is periodically provided, and
the barrier metal is provided on a corner of the hole.

18. The optical filter according to claim 10, wherein
the barrier metal is provided on a corner of the opening on an incident side of light and a corner of the opening on a side of the photoelectric converter.
